(19) United States
(12) Patent Application Publication
(10) Pub. No.: US 2026/0155337 A1
(43) Pub. Date: Jun. 4, 2026

(54) SUBSTRATE PROCESSING APPARATUS, PROTECTOR, METHOD OF MANUFACTURING SEMICONDUCTOR DEVICE, AND RECORDING MEDIUM

(71) Applicant: Kokusai Electric Corporation, Tokyo (JP)

(72) Inventor: Katsuhiko YAMAMOTO, Toyama-shi (JP)

(73) Assignee: Kokusai Electric Corporation, Tokyo (JP)

(21) Appl. No.: 19/337,262

(22) Filed: Sep. 23, 2025

(30) Foreign Application Priority Data
Oct. 16, 2024 (JP) 2024-180825

(51) Int. Cl. H01J 37/32; C23C 16/44; C23C 16/50; C23C 16/52

(52) U.S. Cl. CPC H01J 37/32495; C23C 16/4401; C23C 16/50; C23C 16/52; H01J 37/3244

(57) ABSTRACT

There is provided a technique that includes: a process container configured to process a substrate; a gas supplier configured to be capable of supplying a gas that processes the substrate into the process container; a protector arranged along an inner peripheral surface of the process container, a height of the protector being adjustable by rotation in a circumferential direction; and a controller configured to be capable of performing a control to process the substrate by supplying the gas after the height of the protector is adjusted.

### CROSS-REFERENCE TO RELATED APPLICATION

This application is based upon and claims the benefit of priority from Japanese Patent Application No. 2024-180825, filed on Oct. 16, 2024, the entire contents of which are incorporated herein by reference.

### TECHNICAL FIELD

The present disclosure relates to a substrate processing apparatus, a protector, a method of manufacturing a semiconductor device, and a recording medium.

### BACKGROUND

In related technology, as a process of manufacturing a semiconductor device, there is a case in which a film formed on a substrate is modified by plasma.

### SUMMARY

Some embodiments of the present disclosure provide a technique capable of adjusting a range within which adhesion of reaction by-products and the like to an inner peripheral surface of a process container is suppressed.

According to some embodiments of the present disclosure, there is provided a technique that includes: a process container configured to process a substrate; a gas supplier configured to be capable of supplying a gas that processes the substrate into the process container; a protector arranged along an inner peripheral surface of the process container, a height of the protector being adjustable by rotation in a circumferential direction; and a controller configured to be capable of performing a control to process the substrate by supplying the gas after the height of the protector is adjusted.

### BRIEF DESCRIPTION OF DRAWINGS

The accompanying drawings, which are incorporated in and constitute a part of the specification, illustrate embodiments of the present disclosure.

FIG. 1 is a schematic diagram illustrating a substrate processing apparatus according to embodiments of the present disclosure.

FIG. 2 is a diagram illustrating a state in which a protector is being replaced in a substrate processing apparatus according to embodiments of the present disclosure.

FIG. 3A is a top view of a protector according to embodiments of the present disclosure.

FIG. 3B is a side view of the protector of FIG. 3A.

FIG. 4A is a front view illustrating a state in which a height of a protector is the lowest.

FIG. 4B is a partial cross-sectional view of FIG. 4A. FIG. 4C is a front view illustrating a state in which the height of the protector is the highest. FIG. 4D is a partial cross-sectional view of FIG. 4C.

FIG. 5 is a control block diagram illustrating a controller control system of a substrate processing apparatus according to embodiments of the present disclosure.

FIG. 6 is a flowchart illustrating a substrate processing process according to embodiments of the present disclosure.

FIG. 7A is a top view of a modification of a protector according to embodiments of the present disclosure. FIG. 7B is a side view of the protector of FIG. 7A.

FIG. 8A is a top view of another modification of the protector according to embodiments of the present disclosure. FIG. 8B is a side view of the protector of FIG. 8A.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

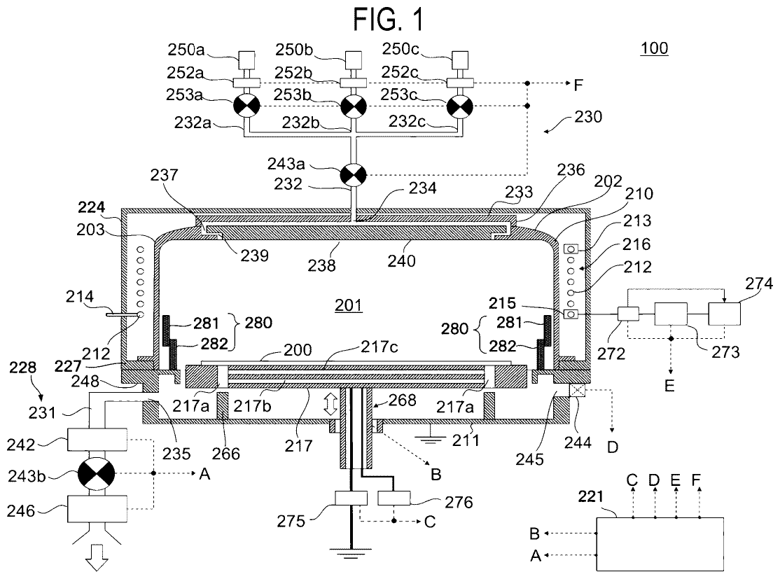

Hereinafter, one aspect of the present disclosure will be described mainly with reference to FIGS. 1 to 8B. The drawings used in the following description are schematic. Dimensional relationships, ratios, and the like of various components shown in the drawings may not match actual ones. Further, even among the drawings, dimensional relationships, ratios, and the like of various components may not match one another.

### (1) Configuration of Substrate Processing Apparatus

A substrate processing apparatus 100 includes, as shown in FIG. 1, a process furnace 202 in which a plasma process is performed on a wafer 200 as a substrate. The process furnace 202 is provided with a process container 203 that constitutes a process chamber 201. That is, the substrate processing apparatus 100 is configured to perform the plasma process on the wafer 200 within the process container 203. The process container 203 includes a dome-shaped upper container 210 and a bowl-shaped lower container 211. Further, the substrate processing apparatus 100 includes a base plate 248 that covers an upper end of the lower container 211 and that is provided with a through-hole formed therein.

The process chamber 201 is formed by covering the lower container 211 with the upper container 210. The upper container 210 is made of quartz (SiO₂), and the lower container 211 is made of, for example, aluminum Al.

In addition, a silicon nitride (SiN) film as a protective film to protect the upper container 210 is formed on an inner peripheral surface of the upper container 210. The upper container 210 is an example of a quartz container.

As shown in FIG. 1, a gate valve 244 is installed at a lower side wall of the lower container 211. When the gate valve 244 is open, the wafer 200 may be loaded into the process chamber 201 or unloaded out of the process chamber 201, via a loading/unloading port 245 by using a transfer mechanism (not shown). When the gate value 244 is closed, the gate valve 244 serves as a gate valve configured to maintain airtightness of the process chamber 201.

The process chamber 201 includes a plasma generation space around which a resonance coil 212 is installed and a substrate processing space which is configured to process the wafer 200 and is in fluid communication with the plasma generation space. The plasma generation space is a space in which plasma is generated, and refers to a space above a lower end of the resonance coil 212 and below an upper end of the resonance coil 212 in the process chamber 201. Further, the substrate processing space is a space in which the wafer 200 is processed by using plasma, and refers to a space below the lower end of the resonance coil 212.

### [Susceptor 217]

The susceptor 217 serving as a substrate stage on which the wafer 200 is placed is arranged at a center of a bottom side of the process chamber 201, as shown in FIG. 1.

A heater 217b serving as a heating mechanism is integrally embedded in the susceptor 217.

The susceptor 217 is electrically insulated from the lower container 211. An impedance adjustment electrode 217c is installed inside the susceptor 217. The impedance adjustment electrode 217c is grounded via an impedance variator 275 as an impedance adjuster.

In addition, the susceptor 217 is provided with a susceptor elevator 268 including a driver configured to raise or lower the susceptor 217. The susceptor 217 is also provided with a through-hole 217a, and a wafer lifting pin 266 is installed at a bottom surface of the lower container 211. When the susceptor 217 is lowered by the susceptor elevator 268, the wafer lifting pin 266 is configured to pass through the through-hole 217a without contacting the susceptor 217.

The substrate stage according to the embodiments of the present disclosure mainly includes the susceptor 217 and the heater 217b.

### [Gas Supplier 230]

The gas supplier 230 is installed above the process chamber 201, as shown in FIG. 1. Specifically, a gas supply head 236 is installed above the process chamber 201, that is, on an upper side of the upper container 210. The gas supply head 236 includes a cap-shaped lid 233, a gas inlet port 234, a buffer chamber 237, an opening 238, a shield plate 240, and a gas outlet port 239 and is configured to be capable of supplying each gas to the process chamber 201.

A gas supply pipe 232 is connected to the gas inlet port 234. A downstream end of a first gas supply pipe 232a configured to supply a first gas, a downstream end of a second gas supply pipe 232b configured to supply a second gas, and an inert gas supply pipe 232c configured to supply an inert gas are connected to the gas supply pipe 232 so as to be joined together.

A mass flow controller (MFC) 252a as a flow rate controller and a valve 253a as an opening/closing valve are installed at the first gas supply pipe 232a in this order from an upstream side. A MFC 252b and a valve 253b are installed at the second gas supply pipe 232b in this order from an upstream side. A MFC 252c and a valve 253c are installed at the inert gas supply pipe 232c in this order from an upstream side. Although not included in the substrate processing apparatus 100, a first gas supply source 250a is installed at an upstream side of the MFC 252a of the first gas supply pipe 232a, a second gas supply source 250b is installed at an upstream side of the MFC 252b of the second gas supply pipe 232b, and an inert gas supply source 250c is installed at an upstream side of the MFC 252c of the inert gas supply pipe 232c.

A valve 243a is installed at the gas supply pipe 232. The gas supplier 230 is configured to be capable of supplying a gas that processes the wafer 200 into the process container 203.

The gas supplier (gas supply system) 230 according to the embodiments of the present disclosure mainly includes the gas supply head 236 (the lid 233, the gas inlet port 234, the buffer chamber 237, the opening 238, the shield plate 240, and the gas outlet port 239), the first gas supply pipe 232a, the second gas supply pipe 232b, the inert gas supply pipe 232c, the MFCs 252a, 252b, and 252c, and the valves 253a, 253b, 253c, and 243a. The gas supplier 230 may further include the first gas supply source 250a, the second gas supply source 250b, and the inert gas supply source 250c.

### [Exhauster 228]

A gas exhaust port 235 configured to exhaust a gas from an interior of the process chamber 201 is installed at a side wall of the lower container 211. An upstream end of a gas exhaust pipe 231 is connected to the gas exhaust port 235. An automatic pressure controller (APC) valve 242 as a pressure regulator (pressure regulating part), a valve 243b as an opening/closing valve, and a vacuum pump 246 as a vacuum exhauster are installed at the gas exhaust pipe 231 in this order from an upstream side.

The exhauster 228 (exhaust system) according to the embodiments of the present disclosure mainly includes the gas exhaust port 235, the gas exhaust pipe 231, the APC valve 242, and the valve 243b. The exhauster 228 may further include the vacuum pump 246.

### [Plasma Generator 216]

As shown in FIG. 1, the plasma generator 216 is installed mainly outside an outer wall of the upper container 210. Specifically, a spiral resonance coil 212 is installed at an outer periphery of the process chamber 201, that is, outside a side wall of the upper container 210 so as to surround the process chamber 201. In other words, the spiral resonance coil 212 is installed so as to surround the process container 203 from the outside of the upper container 210 (which is a side away from a center of the upper container 210) in a radial direction of the upper container 210. The resonance coil 212 serves as an electrode and is an example of a coil.

A radio frequency (RF) sensor 272, a high frequency power supply 273, and a matcher 274 configured to perform impedance matching or output frequency matching for the high frequency power supply 273 are connected to the resonance coil 212.

The high frequency power supply 273 is configured to supply high frequency power (RF power) to the resonance coil 212. The RF sensor 272 is installed at an output side of the high frequency power supply 273 and is configured to monitor information of a traveling wave or a reflected wave of the supplied high frequency power. A reflected wave power monitored by the RF sensor 272 is input to the matcher 274, and the matcher 274 controls an impedance of the high frequency power supply 273 or a frequency of the high frequency power output from the high frequency power supply 273 based on the information of the reflected wave input from the RF sensor 272 so as to minimize the reflected wave.

The high frequency power supply 273 includes a power supply controller (control circuit) including a high frequency oscillation circuit and a preamplifier configured to define an oscillation frequency and output, and an amplifier (output circuit) configured to amplify the output to a predetermined level. The power supply controller controls the amplifier based on output conditions regarding a preset frequency and a preset power by using an operation panel. The amplifier supplies constant high frequency power to the resonance coil 212 via a transmission line.

A winding diameter, a winding pitch, and the number of winding turns of the resonance coil 212 are set for resonance at a constant wavelength so as to form a standing wave of a predetermined wavelength. That is, an electrical length of the resonance coil 212 is set to a length corresponding to an integer multiple (1 time, 2 times, or so on) of one wavelength at a predetermined frequency of the high frequency power supplied from the high frequency power supply 273. In other words, the substrate processing apparatus 100 includes the high frequency power supply 273 configured to supply high frequency power with a wavelength of an integer multiple of the electrical length of the resonance coil 212 to the electrode.

As a material constituting the resonance coil 212, a copper pipe, a copper thin plate, an aluminum pipe, an aluminum thin plate, and a material obtained by depositing copper or aluminum on a polymer belt are used.

Both ends of the resonance coil 212 are electrically grounded. At least one of the two ends of the resonance coil 212 is grounded via a movable tap 213 to finely adjust the electrical length of the resonance coil 212 when the substrate processing apparatus 100 is newly installed or when process conditions are changed. Reference numeral 214 shown in FIG. 1 indicates a fixed ground at the other end of the resonance coil 212. Further, a power feeder constituted by a movable tap 215 is installed between the two grounded ends of the resonance coil 212 to finely adjust the impedance of the resonance coil 212 when the substrate processing apparatus 100 is newly installed or when the process conditions are changed.

The plasma generator 216 according to the embodiments of the present disclosure is mainly constituted by the resonance coil 212, the RF sensor 272, and the matcher 274. The plasma generator 216 may further include the high frequency power supply 273.

### [Shield Plate 224]

As shown in FIG. 1, the shield plate 224 is installed to cover the resonance coil 212 from an outside of the process container 203 in a radial direction of the process container 203, shield an electric field generated by the resonance coil 212, and form a capacitive component (a C component) to constitute a resonance circuit between the shield plate 224 and the resonance coil 212.

Specifically, the shield plate 224 is formed by using a conductive material such as an aluminum alloy. The shield plate 224 includes a lower flange 227 extending inward in a radial direction of the container and is configured to be installed on the base plate 248.

### [Protector 280]

As shown in FIG. 1, the protector 280 is installed on the base plate 248 of the lower container 211 so as to cover an inner peripheral surface of the upper container 210 from an inside of the upper container 210 along an inner peripheral surface of a lower side of the upper container 210 within the process container 203.

Here, when a film is formed on the wafer 200 by supplying a gas into the process container 203, gas components or reaction by-products may adhere to an inner wall of the process container 203. In particular, when the gas components or the reaction by-products adhere to the lower side inside the process container 203, stress is applied to the process container 203 due to heat or vacuum pressure, and damage (e.g., cracks, etc.) may occur on the inner wall of the process container 203. To suppress adhesion of the gas components or the reaction by-products within the process container 203, the protector 280 is installed, before supplying the gas into the process container 203, in an area to which the gas components or the reaction by-products are likely to adhere within the process container 203. As a result, damage to the process container 203 (e.g., occurrence of cracks, etc.) is suppressed, thereby contributing to an extended lifespan of the process container 203.

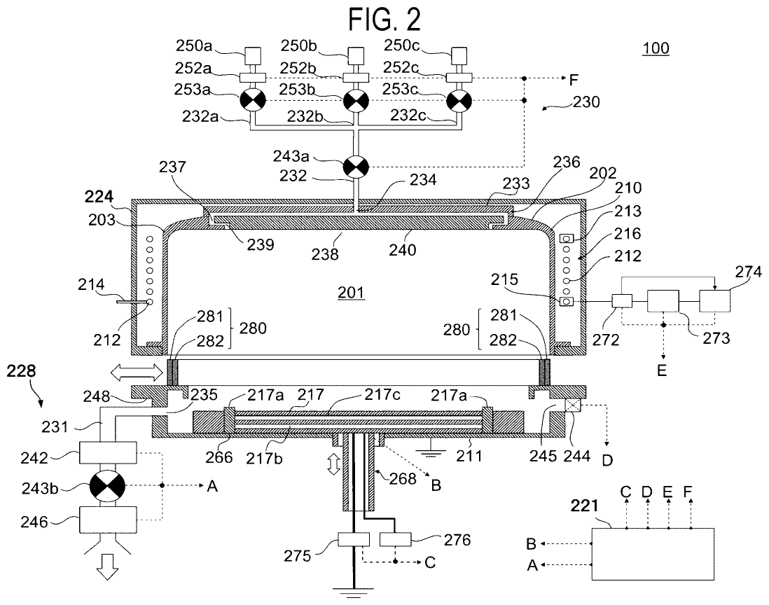

As shown in FIG. 2, the upper container 210 is movable in an upward direction. When performing maintenance work such as replacing the protector 280, the upper container 210 is moved in the upward direction relative to the lower container 211, and the protector 280 to which the gas components or the reaction by-products adhere is moved in a horizontal direction from a maintenance space (maintenance area) which is a space generated between a lower end of the upper container 210 and an upper end of the lower container 21, thereby separating the protector 280 from the inside of the process container 203. Then, the cleaned protector 280 or the new protector 280 is moved in the horizontal direction and is installed inside the process container 203 for replacement. In this case, there is a limit to a height at which the upper container 210 is lifted upward, and the maintenance area is limited.

In the present disclosure, during maintenance work, the protector 280 is adjusted so that the height thereof is decreased to a height at which the protector 280 can be separated from the base plate 248 or installed on the base plate 248. In this case, the height of the protector 280 is lower than the height of the maintenance area. Then, the protector 280 is separated from the base plate 248 of the lower container 211 in the horizontal direction in a state in which the height of the protector 280 is low. Further, the protector 280 is installed on the base plate 248 in the horizontal direction in the state in which the height of the protector 280 is low.

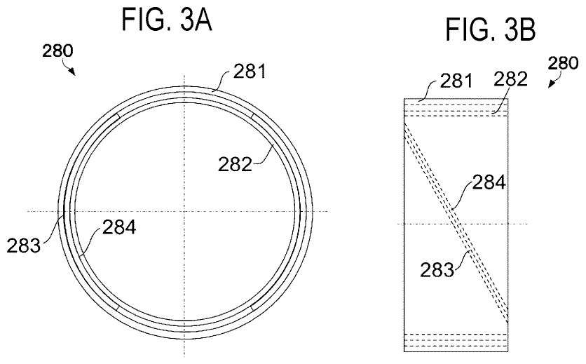

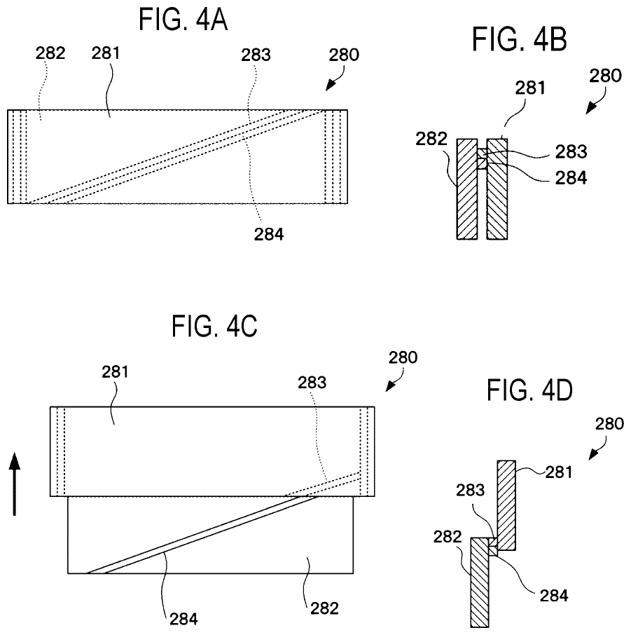

FIG. 3A is a top view of the protector 280, and FIG. 3B is a side view of the protector 280 of FIG. 3A. FIG. 4A is a front view illustrating a state in which the height of the protector 280 is the lowest, and FIG. 4B is a partial cross-sectional view of FIG. 4A. FIG. 4C is a front view illustrating a state in which the height of the protector 280 is the highest, and FIG. 4D is a partial cross-sectional view of FIG. 4C.

The protector 280 is formed in a cylindrical shape and is configured to be divided in two parts in an up-down direction. Specifically, the protector 280 includes a first protector 281 arranged on an outer peripheral side and forming an upper end, and a second protector 282 arranged on an inner peripheral side of the first protector 281 and forming a lower end of the first protector 281. The first protector 281 and the second protector 282 are arranged in a substantially concentric shape when seen in a top view.

A distance from the center of the first protector 281 to an inner peripheral surface of the first protector 281 is configured to be longer than a distance from the center of the second protector 282 to an outer peripheral surface of the second protector 282. In other words, an inner diameter of the first protector 281 is configured to be larger than an outer diameter of the second protector 282. In addition, the second protector 282 is configured to be accommodated inside the first protector 281. A distance from the center of the first protector 281 to an outer peripheral surface of the first protector 281 is shorter than a distance from the center of the process container 203 to an inner peripheral surface of the process container 203. In other words, an outer diameter of the first protector 281 is smaller than an inner diameter of the process container 203. In addition, the outer peripheral surface of the first protector 281 is closer to the inner peripheral surface of the process container 203 than the outer peripheral surface of the second protector 282. Therefore, adhesion of the film to the inner peripheral surface of the process container 203 can be suppressed in a range from an upper end position of the first protector 281 to a lower end position of the second protector 282.

On the inner peripheral surface of the first protector 281, a first protrusion 283 is formed that protrudes in an inclined direction from a lower end to an upper end in a circumferential direction. On the outer peripheral surface of the second protector 282, a second protrusion 284 is formed that projects in an inclined direction from a lower end to an upper end in a circumferential direction. A distance from the center of the first protector 281 to an inner peripheral surface of the first protrusion 283 is longer than a distance from the center of the second protector 282 to an outer peripheral surface of the second protector 282.

A lower end surface of the first protrusion 283 is configured to contact an upper end surface of the second protrusion 284. That is, the protector 280 is configured such that, for example, by rotating the first protector 281 in a counterclockwise direction, the lower end surface of the first protrusion 283 slides on the upper end surface of the second protrusion 284 in the circumferential direction. As a result, the first protector 281 moves upward with respect to the second protector 282, and the height of the protector 280 is adjusted to be increased. In addition, the protector 280 is configured such that, for example, by rotating the first protector 281 in a clockwise direction, the lower end surface of the first protrusion 283 slides on the upper end surface of the second protrusion 284 in a circumferential direction. As a result, the first protector 281 moves downward with respect to the second protector 282, and the height of the protector 280 is adjusted to be decreased. In other words, the protector 280 is configured such that the first protector 281 moves in the vertical direction relative to the second protector 282 by rotation of the first protector 281 in the circumferential direction, thereby enabling height adjustment of the protector 280. That is, the height of the protector 280 can be easily adjusted. In this way, the height of the protector 280 can be adjusted by moving the first protector 281 in an up-down direction relative to the second protector 282.

The inclination of each of the first protrusion 283 and the second protrusion 284 may be configured such that, by rotating the first protector 281 in the clockwise direction, the first protector 281 moves upward relative to the second protector 282, thereby adjusting the height of the protector 280 to be increased, and by rotating the first protector 281 in the counterclockwise direction, the first protector 281 moves downward relative to the second protector 282, thereby adjusting the height of the protector 280 to be decreased.

That is, after the maintenance work is completed, the protector 280 is installed on the base plate 248 with a low height, and the first protector 281 is rotated in the circumferential direction relative to the second protector 282 while the protector 280 is installed on the base plate 248, thereby adjusting the height of the protector 280. That is, before processing the wafer 200 after the maintenance is completed, the height of the protector 280 is adjusted to be increased by rotating the protector 280 in the circumferential direction, thereby extending a protection range within which the gas components or the reaction by-products do not adhere to the process container 203. This reduces a range within which the gas components or the reaction by-products adhere to the inside of the process container 203. That is, the protector 280 is configured to allow height adjustment, making it possible to adjust the height of the protector 280 according to purpose. In addition, the operation of increasing the height of the protector 280 may be performed after the maintenance work is completed and during the maintenance work and may be performed while the upper container 210 is lifted upward.

The protector 280 is installed on the base plate 248 of the lower container 211 along the inner peripheral surface of the lower side of the upper container 210 of the process container 203, as shown in FIG. 1. Thus, it is easy to install the protector 280. The protector 280 and the process container 203 are arranged in a substantially concentric shape when seen in a top view. As a result, adhesion of the gas components or the reaction by-products to the inner peripheral surface of the process container 203 can be suppressed on average (uniformly). A gap between the inner peripheral surface of the process container 203 and the outer peripheral surface of the protector 280 is narrower than 2 mm, and is specifically 1 mm or less. As a result, the adhesion of the gas components or the reaction by-products to the gap between the process container 203 and the protector 280 can be suppressed. Further, by providing the gap between the inner peripheral surface of the process container 203 and the outer peripheral surface of the protector 280, it is possible to prevent the inner peripheral surface of the process container 203 and the outer peripheral surface of the protector 280 from being attached to each other due to the adhesion of the gas components or the reaction by-products. Further, this can reduce an undesired work time during maintenance work caused by such attachment between the inner peripheral surface of the process container 203 and the outer peripheral surface of the protector 280 and avoid generation of particles, etc., when detaching the protector 280 from the process container 203.

In addition, the protector 280 is configured to prevent the supplied gas components or reaction by-products from adhering to the process container 203. Specifically, the protector 280 (i.e., the first protector 281 and the second protector 282) is formed of, for example, SiO₂. As a result, the supplied gas components or reaction by-products can actively adhere to the protector 280, and at least the supplied gas components or reaction by-products can be prevented from adhering to the process container 203. Thus, it is possible to suppress frequency of maintenance, such as cleaning or replacement, inside the process container 203. In addition, it becomes possible to complete maintenance by replacing the protector 280, and an apparatus downtime can be shortened.

### [Controller 221]

As shown in FIG. 1, the controller 221 serving as control part is configured to be capable of controlling the APC valve 242, the valve 243b, and the vacuum pump 246 through a signal line A, the susceptor elevator 268 via a signal line B, and a heater power regulator 276 and the impedance variator 275 via a signal line C. The controller 221 is further configured to be capable of controlling the gate valve 244 via a signal line D, the RF sensor 272, the high frequency power supply 273, and the matcher 274 via a signal line E, and the MFCs 252a to 252c and the valves 253a to 253c, and 243a via a signal line F.

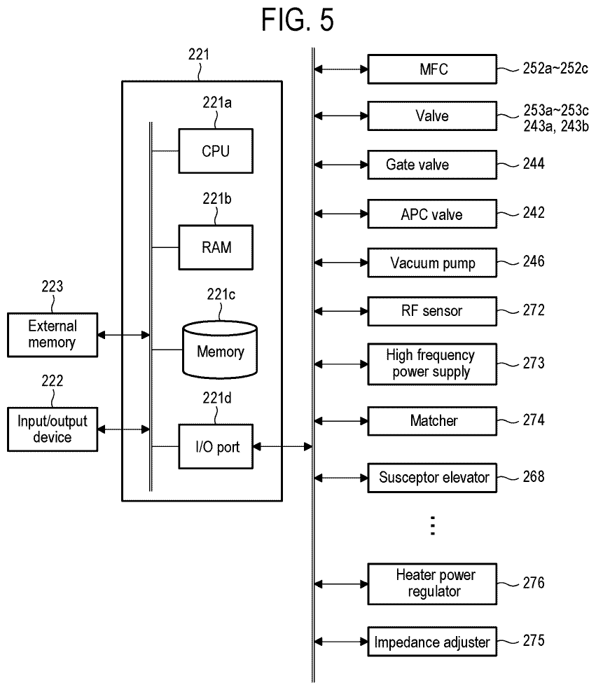

As shown in FIG. 5, the controller 221 is constituted as a computer including a central processing unit (CPU) 221a, a random access memory (RAM) 221b, a memory 221c, and an I/O port 221d. The RAM 221b, the memory 221c, and the I/O port 221d is configured to be capable of exchanging data with the CPU 221a via an internal bus 221e. For example, an input/output device 222 including, for example, a touch panel, a display, or the like is connected to the controller 221.

Here, the input/output device 222 is configured to receive process conditions for processing the wafer 200 or execution operations for substrate processing. Further, the input/output device 222 is configured to display the state of the substrate processing apparatus 100.

The memory 221c is constituted by, for example, a flash memory, a hard disk drive (HDD), and the like. A control program configured to control operations of the substrate processing apparatus 100, and a process recipe in which sequences and conditions of a substrate processing process described below are written or a recipe execution program that executes the process recipe is readably stored in the memory 221c.

The recipe execution program functions as program that is combined to cause the CPU 221a to execute each sequence in the substrate processing process described below so as to obtain a predetermined result. Hereinafter, the recipe execution program or the control program will be generally and simply referred to simply as a program (program product). The term “program” used herein may refer to a recipe execution program alone, a control program alone, or both the recipe execution program and the control program. Further, the RAM 221b functions as a memory area (work area) in which a program or data read by the CPU 221a is temporarily stored.

According to the embodiments of the present disclosure, each process condition is stored in the memory 221c. The process conditions include at least one condition selected from the group of a temperature of the wafer 200 to be processed, a pressure of the process chamber 201, a type of a process gas that processes the wafer 200, a flow rate of the process gas that processes the wafer 200, and electric power supplied to the resonance coil 212.

The I/O port 221d is electrically connected to the MFCs 252a to 252c, the valves 253a to 253c, 243a, and 243b, the gate valve 244, the APC valve 242, the vacuum pump 246, the RF sensor 272, the high frequency power supply 273, the matcher 274, the susceptor elevator 268, the heater power regulator 276, and the impedance variator 275.

The CPU 221a is configured to read and execute the control program stored in the memory 221c and to read the process recipe stored in the memory 221c according to input of an operation command from the input/output device 222.

The CPU 221a is configured to control an opening degree adjusting operation of the APC valve 242, an opening/closing operation of the valve 243b, and a start and stop operation of the vacuum pump 246 via the I/O port 221d and the signal line A, according to the content of the read process recipe. Further, the CPU 221a is configured to control an operation of raising or lowering the susceptor elevator 268 via the signal line B, an operation of adjusting an amount of power (temperature adjusting operation) supplied to the heater 217b by the heater power regulator 276 and the impedance variator 275 via the signal line C, and an opening/closing operation of the gate valve 244 via the signal line D. Further, the CPU 221a is configured to control operations of the RF sensor 272, the matcher 274, and the high frequency power supply 273 via the signal line E and flow rate adjusting operations of the MFCs 252a to 252c for various types of gases and an opening/closing operation of the valves 253a to 253c, and 243a via the signal line F.

The controller 221 may be constituted by installing, on a computer, the above-described program stored in an external memory (e.g., a magnetic disk such as a magnetic tape, a flexible disk or a hard disk, an optical disc such as a CD or DVD, a magneto-optical disc such as an MO, a semiconductor memory such as a USB memory or a memory card) 223. The memory 221c or the external memory 223 is constituted as a computer-readable recording medium. Hereinafter, the memory 221c and the external memory 223 are also generally and simply referred to simply as a recording media. When the term “recording medium” is used herein, this may include the memory 221c alone, the external memory 223 alone, or both the memory 221c and the external memory 223. In addition, the program may be provided to the computer by using a communication means such as the Internet or a dedicated line instead of using the external memory 223, or a program provided by a communication means such as the Internet or the dedicated line may be stored in the recording medium and then used.

### (2) Substrate Processing Process

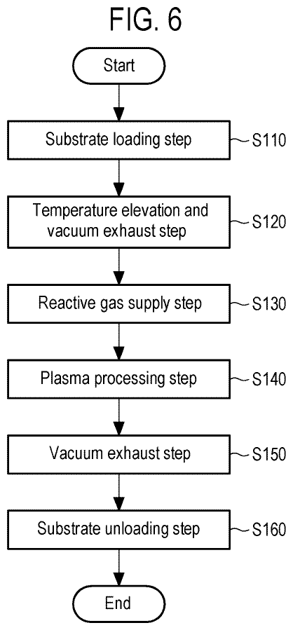

An example of a sequence for forming a film containing a predetermined element on the wafer 200 as a substrate processing process in a process of manufacturing a semiconductor device by using the above-described substrate processing apparatus 100 will be described with reference to FIG. 6. In the following description, operations of respective components constituting the substrate processing apparatus 100 are controlled by the controller 221.

[installation of Protector 280]

First, before starting the substrate processing process, the protector 280 is installed in the process container 203. In this case, pressure inside the process chamber 201 is adjusted to atmospheric pressure. Specifically, the upper container 210 is moved in the upward direction, and the protector 280 is moved horizontally from the maintenance area and installed on the base plate 248 along the inner peripheral surface of the lower side of the upper container 210. In this case, the protector 280 and the process container 203 are arranged in a substantially concentric shape when seen in a top view. A gap between the inner peripheral surface of the process container 203 and the outer peripheral surface of the protector 280 is set to be narrower than 2 mm. Then, the height of the protector 280 is adjusted by rotating the protector 280 in the circumferential direction. After the height of the protector 280 is adjusted, the upper container 210 is moved downward. Thereafter, the opening degree of the APC valve 242 is adjusted, the pressure inside the process chamber 201 is adjusted to the same pressure as pressure of the vacuum transfer chamber adjacent to the process chamber 201, and then the following steps S110 to S160 are performed.

### [Substrate Loading Step S110]

In the substrate loading step S110, the wafer 200 is loaded into the process chamber 201.

Specifically, the susceptor elevator 268 lowers the susceptor 217 to a transfer position of the wafer 200, allowing the wafer lifting pin 266 to pass through the through-hole 217a of the susceptor 217.

Subsequently, the gate valve 244 is opened, and the wafer 200 is loaded into the process chamber 201 from the vacuum transfer chamber adjacent to the process chamber 201 by using a wafer transfer mechanism (not shown). The loaded wafer 200 is supported in a horizontal position on the wafer lifting pin 266 protruding from the surface of the susceptor 217. After the wafer 200 is loaded into the process chamber 201, the wafer transfer mechanism is withdrawn out of the process chamber 201, and the gate valve 244 is closed to seal the process chamber 201. Then, the susceptor elevator 268 raises the susceptor 217, such that the wafer 200 is supported on the upper surface of the susceptor 217.

### [Temperature Elevation and Vacuum Exhaust Step S120]

In the temperature elevation and vacuum exhaust step S120, the temperature of the wafer 200 loaded into the process chamber 201 is elevated.

The heater 217b is heated in advance. By holding the wafer 200 on the susceptor 217 in which the heater 217b is embedded, the wafer 200 is heated to a target temperature. While the temperature of the wafer 200 is elevated, the process chamber 201 is vacuum-exhausted by the vacuum pump 246 via the gas exhaust pipe 231, and the pressure of the process chamber 201 is set to a predetermined value. The vacuum pump 246 is kept in operation at least until a substrate unloading step S160 described below is completed.

### [Reactive Gas Supply Step S130]

In the reactive gas supply step S130, the supply of the first gas and the second gas serving as reactive gases is initiated. Specifically, the valves 253a and 253b are opened, and the supply of the first gas and the second gas to the process chamber 201 is initiated while controlling flow rates of the first gas and the second gas in the MFCs 252a and 252b.

In addition, the exhaust of the process chamber 201 is controlled by adjusting the opening degree of the APC valve 242 so that the process chamber 201 reaches a target pressure. In this way, while appropriately exhausting the process chamber 201, the supply of the first gas and the second gas continues until the end of a plasma processing step S140, which is described below.

As the first gas, for example, an oxygen-containing gas may be used. As the oxygen-containing gas, for example, oxygen (O₂) gas may be used.

As the second gas, for example, a hydrogen-containing gas may be used. As the hydrogen-containing gas, for example, hydrogen (H₂) gas may be used.

### [Plasma Processing Step S140]

After the pressure of the process chamber 201 is stabilized, in the plasma processing step S140, the supply of high frequency power from the high frequency power supply 273 to the resonance coil 212 via the RF sensor 272 is initiated.

As a result, a high frequency electric field is formed in the plasma generation space to which the first gas and the second gas are supplied. By this electric field, toroidal induction plasma with the highest plasma density is excited at a height position corresponding to an electric midpoint of the resonance coil 212 of the plasma generation space. The first gas and the second gas in the plasma state are plasma-excited and dissociated, and radicals (active species) or reactive species such as ions of elements contained in the first gas and the second gas are generated. Specifically, reactive species such as oxygen radicals containing oxygen (oxygen active species) or oxygen ions, hydrogen radicals containing hydrogen (hydrogen active species) or hydrogen ions are generated.

Radicals and ions generated by the induction plasma are supplied into a trench on the surface of the wafer 200 held on the susceptor 217 in the substrate processing space. The supplied radicals and ions react with a side wall of the trench to modify a layer formed on the surface. Specifically, for example, a silicon layer formed on the surface is modified into a silicon oxide layer.

Thereafter, when a predetermined processing time elapses, the supply of power from the high frequency power supply 273 is stopped, and plasma discharge in the process chamber 201 is stopped. Further, the valves 253a and 253b are closed, and the supply of the first gas and the second gas to the process chamber 201 is stopped. In this way, the plasma processing step S140 is ended. The term “processing time” used herein refers to a time during which related processing is continued. The same applies to the following description.

### [Vacuum Exhaust Step S150]

After the supply of the first gas and the second gas is stopped, in the vacuum exhaust step S150, the inside of the process chamber 201 is vacuum-exhausted via the gas exhaust pipe 231. As a result, the first gas or the second gas of the process chamber 201 and an exhaust gas generated by the reaction of these gases are exhausted to the outside of the process chamber 201. Thereafter, the opening degree of the APC valve 242 is adjusted such that the pressure of the process chamber 201 is adjusted to the same pressure as the pressure of the vacuum transfer chamber (to which the wafer 200 is unloaded, not shown) adjacent to the process chamber 201.

### [Substrate Unloading Step S160]

After the pressure inside the process chamber 201 is adjusted to a predetermined pressure, in the substrate unloading step S160, the susceptor 217 is lowered to the transfer position of the wafer 200, and the wafer 200 is supported on the wafer lifting pin 266. Then, the gate valve 244 is opened, and the wafer 200 is unloaded to the outside of the process chamber 201 by using the wafer transfer mechanism. In this way, the substrate processing process according to the embodiments of the present disclosure is completed.

### [Maintenance Step]

After the substrate processing process is performed multiple times, maintenance of the substrate processing apparatus 100 is performed. In this case, the opening degree of the APC valve 242 is adjusted so that the pressure inside the process chamber 201 is adjusted to an atmospheric pressure state. Specifically, the upper container 210 is moved in the upward direction, and the first protector 281 is rotated in the circumferential direction relative to the second protector 282 so that the protector 280 to which gas components or reaction by-products adhere reaches a height at which the protector can be separated from the base plate 248, thereby adjusting the height of the protector 280 to be decreased. The protector 280 is moved horizontally and separated from the process container 203, and the maintenance is performed.

### (3) Conclusion

According to the present disclosure, one or more effects below are obtained.

As described above, in the substrate processing apparatus 100, the protector 280, the height of which is adjustable, is installed along the inner peripheral surface of the process container 203. As a result, a range can be adjusted within which adhesion of components of a gas supplied into the process container 203 or reaction by-products to the inner peripheral surface of the process container 203 is suppressed.

In addition, since the protector 280 can be installed by adjusting the height thereof to an area in which the gas components or reaction by-products are likely to adhere inside the process container 203, adhesion of the gas components or the reaction by-products to the inside of the process container 203 can be suppressed. As a result, occurrence of cracks in the process container 203 is suppressed, and the lifespan of the process container 203 can be extended.

Further, since the protector 280 inside the process container 203 can be replaced by moving the upper container 210 in the upward direction, the replacement of the protector 280 can be easily performed.

Furthermore, since the first protector 281 is moved in the vertical direction by rotation of the first protector 281 in the circumferential direction, it is possible to adjust the height of the protector 280. Therefore, even when a maintenance area is limited, the height of the protector 280 can be easily adjusted.

### (4) Other Embodiments of Present Disclosure

Next, other embodiments of the above-described protector 280 will be described.

### First Modification

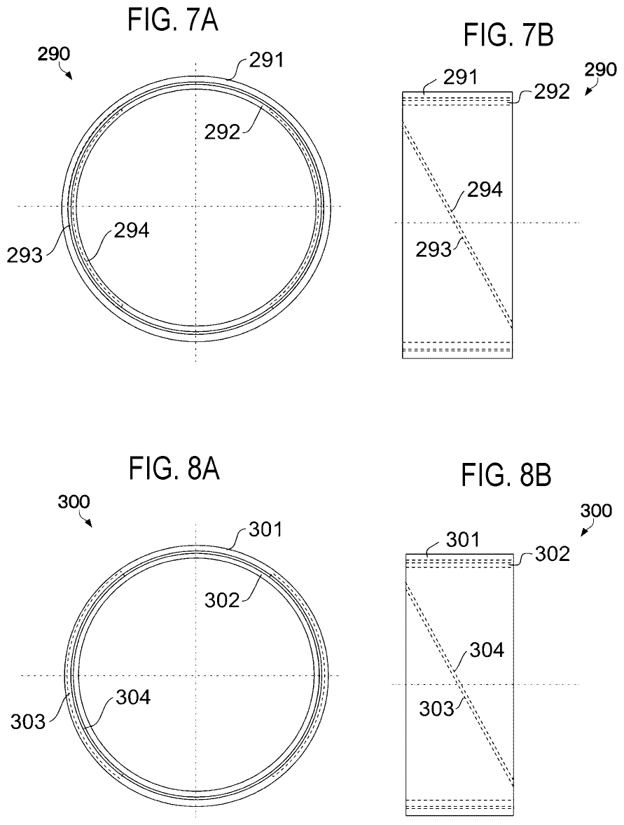

FIGS. 7A and 7B are diagrams illustrating a first modification of the above-described protector. A protector 290 according to the first modification includes a first protector 291 arranged on an outer peripheral side and forming an upper end, and a second protector 292 arranged on an inner peripheral side of the first protector 291 and forming a lower end of the first protector 291. The first protector 291 and the second protector 292 are arranged in a substantially concentric shape when seen in a top view.

A distance from the center of the first protector 291 to the inner peripheral surface of the first protector 291 is longer than a distance from the center of the second protector 292 to the outer peripheral surface of the second protector 292. That is, the second protector 292 is configured to be accommodated inside the first protector 291.

On the inner peripheral surface of the first protector 291, a protrusion 293 is formed that is inclined in an inclined direction from a lower end to an upper end in the circumferential direction and protrudes toward the center. Further, on the outer peripheral surface of the second protector 292, a recess 294 is formed that is inclined in an inclined direction from a lower end to an upper end in the circumferential direction and becomes recessed toward the center. A distance from the center of the first protector 291 to the inner peripheral surface of the protrusion 293 is longer than a distance from the center of the second protector 292 to the outer peripheral surface of the recess 294, that is, a distance from the outer peripheral surface of the second protector 292 to a bottom (also referred to as a bottom surface) that constitutes the recess 294 that becomes recessed.

The protrusion 293 is fitted into the recess 294 and is configured to slide within the recess 294 in the circumferential direction. That is, the protector 290 slides in the circumferential direction in a state in which the protrusion 293 is fitted into the recess 294 by rotating the first protector 291, for example, in a counterclockwise direction. Thus, the first protector 291 moves upward with respect to the second protector 292 to adjust the height of the protector 290 to be increased. Similarly, the protector 290 slides in the circumferential direction in a state in which the protrusion 293 is fitted into the recess 294 by rotating the first protector 291, for example, in a clockwise direction. Thus, the first protector 291 moves downward with respect to the second protector 292 to adjust the height of the protector 290 to be decreased. That is, the protector 290 is configured such that the first protector 291 moves in the vertical direction relative to the second protector 292 by rotation of the first protector 291 in the circumferential direction, thereby enabling height adjustment of the protector 290. In this modification as well, the same effects as in the above-described embodiments are obtained.

Further, the inclination of each of protrusion 293 and the recess 294 may be configured such that, by rotating the first protector 291 in the clockwise direction, the first protector 291 moves upward relative to the second protector 292, thereby adjusting the height of the protector 290 to be increased, and by rotating the first protector 291 in the counterclockwise direction, the first protector 291 moves downward relative to the second protector 292, thereby adjusting the height of the protector 290 to be decreased.

### Second Modification

FIGS. 8A and 8B are diagrams illustrating a second modification of the above-described protector. A protector 300 according to the second modification includes a first protector 301 arranged on an outer peripheral side and forming an upper end, and a second protector 302 arranged on an inner peripheral side of the first protector 301 and forming a lower end of the first protector 301. The first protector 301 and the second protector 302 are arranged in a substantially concentric shape when seen in a top view.

A distance from the center of the first protector 301 to an inner peripheral surface of the first protector 301 is longer than a distance from the center of the second protector 302 to an outer peripheral surface of the second protector 302. That is, the second protector 302 is accommodated inside the first protector 301.

On the inner peripheral surface of the first protector 301, a recess 303 is formed that is inclined in an inclined direction from a lower end to an upper end in the circumferential direction and becomes recessed. In addition, on the outer peripheral surface of the second protector 302, a protrusion 304 is formed that is inclined in an inclined direction from a lower end to an upper end in the circumferential direction and protrudes. A distance from the center of the first protector 301 to the inner peripheral surface of the recess 303, that is, a distance from the inner peripheral surface of the first protector 301 to a bottom (also referred to as a bottom surface) that constitutes the recess 303 that becomes recessed, is longer than a distance from the center of the second protector 302 to the outer peripheral surface of the protrusion 304.

The protrusion 304 is fitted into the recess 303 and is configured to slide in the circumferential direction. That is, the protector 300 slides in the circumferential direction in a state in which the protrusion 304 is fitted into the recess 303 by rotating the first protector 301, for example, in a counterclockwise direction. Thus, the first protector 301 moves upward with respect to the second protector 302 to adjust the height of the protector 300 to be increased. Similarly, the protector 300 slides in the circumferential direction in a state in which the protrusion 304 is fitted into the recess 303 by rotating the first protector 301, for example, in a clockwise direction. Thus, the first protector 301 moves downward with respect to the second protector 302 to adjust the height of the protector 300 to be decreased. That is, the protector 300 is configured such that the first protector 301 moves in the vertical direction relative to the second protector 302 by rotation of the first protector 301 in the circumferential direction, thereby enabling height adjustment of the protector 300. In this modification as well, the same effects as in the above-described embodiments are obtained.

Further, the inclination of each of the protrusion 304 and the recess 303 may be configured such that, by rotating the first protector 301 in the clockwise direction, the first protector 301 moves upward relative to the second protector 302, thereby adjusting the height of the protector 300 to be increased, and by rotating the first protector 301 in the counterclockwise direction, the first protector 301 moves downward relative to the second protector 302, thereby adjusting the height of the protector 300 to be decreased.

While the embodiments of the present disclosure are described above in detail, it is apparent to those skilled in the art that the present disclosure is not limited to the related embodiments and that various other embodiments are possible within the scope of the present disclosure.

While, in the above-described embodiments, the protector 280 is described by using an example in which the protector 280 is formed by using SiO₂, the present disclosure is not limited thereto and the protector 280 may be formed by using other materials.

While, in the above-described embodiments, the protector 280 is described by using an example in which the protector 280 is constituted by being divided into two parts such as the first protector 281 and the second protector 282, the present disclosure is not limited thereto and the protector 280 may be constituted by being divided into three or more parts to adjust the height of the protector 280.

Although not specifically described in the above embodiments, unless otherwise explicitly excluded in the specification, each element is not limited to being singular and may be present in plural.

In the above-described embodiments, an example is described in which a film is formed by using a single-wafer type substrate processing apparatus configured to process one or several substrates at a time. However, the present disclosure is not limited to the above-described embodiments and may also be suitably applied to the case in which a film is formed by using a batch-type substrate processing apparatus configured to process a plurality of substrates at a time. In addition, in the above-described embodiments, an example is described in which a film is formed by using the substrate processing apparatus including a cold-wall type process furnace. However, the present disclosure is not limited to the above-described embodiments and may also be suitably applied to the case in which a film is formed by using a substrate processing apparatus including a hot-wall type process furnace.

Even when such substrate processing apparatuses are used, each process may be performed in the same process sequences and under the same process conditions as in the above-described embodiments or modifications, and the same effects as in the above-described embodiments are obtained.

The above-described embodiments or modifications may be appropriately combined and used. In such cases, process sequences and process conditions may be the same as those of the above-described embodiments or modifications.

According to the present disclosure in some embodiments, it is possible to adjust a range within which adhesion of reaction by-products and the like to an inner peripheral surface of a process container is suppressed.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus, comprising:
a process container configured to process a substrate;
a gas supplier configured to be capable of supplying a gas that processes the substrate into the process container;
a protector arranged along an inner peripheral surface of the process container, a height of the protector being adjustable by rotation in a circumferential direction; and
a controller configured to be capable of performing a control to process the substrate by supplying the gas after the height of the protector is adjusted.

2. The substrate processing apparatus of claim 1, wherein the protector is divided in an up-down direction and includes a first protector as an upper end and a second protector as a lower end.

3. The substrate processing apparatus of claim 2, wherein a distance from a center of the first protector to an inner peripheral surface of the first protector is longer than a distance from a center of the second protector to an outer peripheral surface of the second protector.

4. The substrate processing apparatus of claim 3, wherein protrusions inclined in the circumferential direction are respectively formed on the inner peripheral surface of the first protector and the outer peripheral surface of the second protector.

5. The substrate processing apparatus of claim 3, wherein the first protector includes a first protrusion inclined in a direction from a lower end to an upper end of the inner peripheral surface of the first protector, and
wherein the second protector includes a second protrusion inclined in a direction from a lower end to an upper end of the outer peripheral surface of the second protector.

6. The substrate processing apparatus of claim 5, wherein a lower end surface of the first protrusion contacts an upper end surface of the second protrusion.

7. The substrate processing apparatus of claim 5, wherein a distance from the center of the first protector to an inner peripheral surface of the first protrusion is longer than a distance from the center of the second protector to an outer peripheral surface of the second protector.

8. The substrate processing apparatus of claim 2, wherein the first protector and the second protector are arranged in a substantially concentric shape when seen in a top view.

9. The substrate processing apparatus of claim 6, wherein the protector is configured such that the height of the protector is adjusted in a vertical direction by rotation of the first protector in the circumferential direction.

10. The substrate processing apparatus of claim 9, the protector is configured such that the height of the protector is adjusted by sliding the lower end surface of the first protrusion on the upper end surface of the second protrusion in the circumferential direction.

11. The substrate processing apparatus of claim 1, wherein the protector is configured to be removable from the process container.

12. The substrate processing apparatus of claim 1, wherein the process container includes an upper container and a lower container, and the upper container is movable in an upward direction, and
wherein the protector is configured such that the height of the protector when the protector is lowered is configured to be lower than a height of a space generated between a lower end of the upper container and an upper end of the lower container when the upper container is moved in the upward direction.

13. The substrate processing apparatus of claim 12, wherein the protector is arranged in the lower container.

14. The substrate processing apparatus of claim 1, wherein a gap between the inner peripheral surface of the process container and an outer peripheral surface of the protector is configured to be capable of suppressing adhesion of the gas between the process container and the protector.

15. The substrate processing apparatus of claim 1, wherein the protector is configured to prevent at least adhesion of the supplied gas to the process container.

16. The substrate processing apparatus of claim 1, wherein the protector and the process container are arranged in a substantially concentric shape when seen in a top view.

17. The substrate processing apparatus of claim 1, wherein the protector is adjusted such that the height of the protector is increased before processing the substrate and is adjusted such that the height of the protector is decreased during maintenance work.

18. A protector,
wherein the protector is arranged along an inner peripheral surface of a process container configured to process a substrate, and
wherein a height of the protector is adjustable by rotation in a circumferential direction.

19. A method of manufacturing a semiconductor device, the method comprising:
adjusting the height of the protector of claim 18; and
processing the substrate by supplying a gas into the process container.

20. A non-transitory computer-readable recording medium storing a program that causes, by a computer, a substrate processing apparatus to perform a process comprising:
processing a substrate by supplying a gas into a process container where a protector is arranged along an inner peripheral surface of the process container, a height of the protector being adjusted by rotation in a circumferential direction.
